(19) United States
(12) Patent Application Publication
(10) Pub. No.: US 2025/0255079 A1
(43) Pub. Date: Aug. 7, 2025

(54) DISPLAY MODULE COMPRISING COLOR FILTER

(71) Applicant: SAMSUNG ELECTRONICS CO., LTD., Suwon-si (KR)

(72) Inventors: Heebum ROH, Suwon-si (KR); Jihoon KANG, Suwon-si (KR); Yeseul PARK, Suwon-si (KR); Sanghyun SOHN, Suwon-si (KR)

(73) Assignee: SAMSUNG ELECTRONICS CO., LTD., Suwon-si (KR)

(21) Appl. No.: 19/094,410

(22) Filed: Mar. 28, 2025

Related U.S. Application Data
(63) Continuation of application No. PCT/KR2023/012040, filed on Aug. 14, 2023.

(30) Foreign Application Priority Data
Sep. 30, 2022 (KR) 10-2022-0125399

(51) Int. Cl. H10H 29/851; H10H 29/30; H10H 29/85

(52) U.S. Cl. CPC H10H 29/8513; H10H 29/30; H10H 29/8517

(57) ABSTRACT

A display module includes a substrate and a plurality of pixels on the substrate. Each pixel of the plurality of pixels includes a self-luminescence layer, a first color conversion layer and a second color conversion layer on the self-luminescence layer, a first color filter and a second color filter on the first color conversion layer and the second color conversion layer, a third color filter adjacent to the first color filter and the second color filter, and a size of the third color filter is larger than a size of the first color filter and a size of the second color filter; and partition walls between the first color filter and the second color filter and between the second color filter and the third color filter, and blue dye on the partition walls.

### CROSS-REFERENCE TO RELATED APPLICATIONS

This application is a continuation application of International Application No. PCT/KR2023/012040, filed on Aug. 14, 2023, which claims priority to Korean Patent Application No. 10-2022-0125399, filed on Sep. 30, 2022, in the Korean Intellectual Property Office, the disclosures of which are incorporated by reference herein in their entireties.

### BACKGROUND

### 1. Field

The disclosure relates to a display module including a color filter, and more particularly, to a display module that has a structure of optically converting a blue light source into a red light and a green light through red and green color conversion layers.

### 2. Description of Related Art

When self-luminescence elements for displaying images are used for a display panel, an image can be displayed without a backlight. A display panel expresses various colors as it operates in pixel or sub-pixel units consisting of self-luminescence elements. Operations of each pixel or sub-pixel are controlled by a thin film transistor (TFT).

A display module that provides images by using self-luminescence elements has a structure of optically converting a blue light source that emits a light by self-luminescence elements into a red light and a green light through red and green color conversion layers. Here, the display module may include a color filter for the purpose of blocking leakage of a blue light in the upper part of a color conversion layer, and blocking an external light.

A conventional color filter is located in the upper parts of red and green color conversion layers over a blue light source, and performs a role of blocking light emission of the color conversion layers by an external light. As the red and green color conversion layers get to emit lights by a blue light that is emitted by self-luminescence elements, lights of a blue area included in an external light should be kept from reaching the color conversion layers. Here, the red color filter, the green color filter, and the blue color filter respectively make only lights of red, green, and blue areas pass through, and only lights of the red area and the green area among the external lights that passed the color filters get to reach the red and green color conversion layers, and thus the color conversion layers are not made to emit lights by lights of the blue area among the external lights that passed through the color filters.

The red and green color conversion layers get to reflect lights of the red area and the green area among the external lights that passed through the color filters to the upper parts. In contrast, the color filter that makes lights of the blue area among the external lights that passed through the color filters pass through does not include separate color conversion layers in the lower part, but includes a transparent resin layer, and thus relatively less reflection occurs compared to other colors.

Accordingly, in a spectrum of a reflective light by an external light, the strength of the red and green areas is shown to be relatively higher than that of the blue area. Thus, when the display module is turned off, a problem that the surface of the display module seems yellowish occurs. Also, due to such an uneven spectrum of a reflective light by an external light, a color mixing phenomenon may be generated when the display module is driven in a low grayscale.

### SUMMARY

According to an aspect of the disclosure, there is provided a display module including: a substrate; and a plurality of pixels on the substrate, wherein each pixel of the plurality of pixels includes: a self-luminescence layer; a first color conversion layer and a second color conversion layer on the self-luminescence layer; a first color filter and a second color filter on the first color conversion layer and the second color conversion layer; a third color filter adjacent to the first color filter and the second color filter, and a size of the third color filter is larger than a size of the first color filter and a size of the second color filter; and partition walls between the first color filter and the second color filter, and partition walls between the second color filter and the third color filter, and blue dye on the partition walls.

The self-luminescence layer may include blue micro light emitting diodes (LEDs).

The first color conversion layer may include a first color conversion material that emits lights of a red wavelength band, and wherein the second color conversion layer may include a second color conversion material that emits lights of a green wavelength band.

The first color conversion material included in the first color conversion layer may be a red quantum dot or a red nano phosphor, and wherein the second color conversion material included in the second color conversion layer may be a green quantum dot or a green nano phosphor.

The display module may further include transparent resin layer on self-luminescence elements and the transparent resin layer may be adjacent to the first color conversion layer and the second color conversion layer.

The third color filter may be on the transparent resin layer.

The self-luminescence layer may include a first self-luminescence element, a second self-luminescence element, and a third self-luminescence element, wherein the first color conversion layer on a light emitting surface of the first self-luminescence element, wherein the second color conversion layer may be on a light emitting surface of the second self-luminescence element, and the transparent resin layer may be provided on a light emitting surface of the third self-luminescence element.

A size of the first self-luminescence element may be identical to a size of the second self-luminescence element, which may be identical to a size of the third self-luminescence element.

A first value may correspond to a result of multiplying the size of the first color filter with a reflectance of a red color in upper parts of the first color filter, the second color filter, and the third color filter, wherein a second value may correspond to a result of multiplying the size of the second color filter with a reflectance of a green color in upper parts of the first color filter, the second color filter, and the third color filter, wherein a third value may correspond to a result of multiplying the size of the third color filter with a reflectance of a blue color in upper parts of the first color filter, the second color filter, and the third color filter, and wherein the first value, the second value, and the third value may be within a threshold range.

Widths of the first color filter, the second color filter, and the third color filter may be identical, and a length of the third color filter may be longer than a length of the first color filter and a length of second color filter.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a schematic front view illustrating a display module according to an embodiment of the disclosure;

FIG. 2 is a schematic block diagram illustrating a display module according to an embodiment of the disclosure;

FIG. 3 is a diagram schematically illustrating pixels included in a display module according to an embodiment of the disclosure;

FIG. 4 is a cross-sectional view illustrating pixels included in a display module according to an embodiment of the disclosure;

FIG. 5 and FIG. 6 are diagrams illustrating a plurality of color filters included in a display module according to an embodiment of the disclosure;

FIG. 7 is a diagram illustrating a spectrum for a reflective light of an external light obtained through a related art color filter and a spectrum for a reflective light of an external light obtained after extending the size of a blue color filter according to an embodiment of the disclosure; and

FIG. 8 is a diagram illustrating a CIE coordinate for a reflective light of an external light obtained through a related art color filter and a CIE coordinate for a reflective light of an external light obtained after extending the size of a blue color filter according to an embodiment of the disclosure.

### DETAILED DESCRIPTION

Hereinafter, various embodiments will be described in more detail with reference to the accompanying drawings. The embodiments described in this disclosure may be modified in various ways. Also, specific embodiments may be illustrated in the drawings, and described in detail in the detailed description. However, specific embodiments disclosed in the accompanying drawings are for making the various embodiments easily understood. Accordingly, the technical idea of the disclosure is not restricted by the specific embodiments disclosed in the accompanying drawings, and the embodiments should be understood as including all equivalents or alternatives included in the idea and the technical scope of the disclosure.

Also, in the disclosure, terms including ordinal numbers such as ‘the first’ and ‘the second’ may be used to describe various components, but these components are not limited by the aforementioned terms. The aforementioned terms are used only for the purpose of distinguishing one component from another component.

In addition, in the disclosure, terms such as “include” and “have” should be construed as designating that there are such characteristics, numbers, steps, operations, elements, components, or a combination thereof described in the specification, but not as excluding in advance the existence or possibility of adding one or more of other characteristics, numbers, steps, operations, elements, components, or a combination thereof. Also, the description in the disclosure that an element is “coupled with/to” or “connected to” another element should be interpreted to mean that the one element may be directly coupled with/to or connected to the another element, but still another element may exist between the elements. In contrast, the description that one element is “directly coupled” or “directly connected” to another element can be interpreted to mean that still another element does not exist between the one element and the another element.

Further, in the disclosure, the expression ‘identical’ not only means that some features perfectly coincide, but also means that the features include a difference in consideration of a machining error range.

Other than the above, in describing the disclosure, in case it is determined that detailed explanation of related known functions or features may unnecessarily confuse the gist of the disclosure, the detailed explanation will be abridged or omitted.

In the disclosure, a display module may be a display panel including micro light emitting diodes which are self-luminescence elements for displaying images. A display module is a kind of flat display panel, and consists of a plurality of inorganic LEDs, each of which is 100 μm or smaller, and provides better contrast, response time, and energy efficiency than a liquid crystal display (LCD) panel which needs a backlight. Also, in a display module, micro light emitting diodes which are used for displaying images are self-luminescence elements, and thus it is not necessary to include a separate backlight.

In the disclosure, organic LEDs and micro LEDs which are inorganic light emitting diodes all have good energy efficiency, but micro LEDs have better brightness and light emitting efficiency, and a longer lifespan than OLEDs. Micro LEDs may be a semiconductor chip that can emit a light by itself in case power is supplied. Micro LEDs have fast response speed, low power consumption, and high luminance. For example, micro LEDs have higher efficiency in converting electricity into photons than a related art liquid crystal display (LCD) or organic light emitting diodes (OLEDs). That is, micro LEDs have higher “brightness per watt” than a related art LCD or an OLED display. Accordingly, micro LEDs can exert identical brightness with about half the energy compared to related art LEDs (of which length, width, and height respectively exceed 100 μm) or OLEDs. In addition, micro LEDs can implement a high resolution, excellent colors, contrast, and brightness, and thus they can express colors in a wide range correctly, and can implement a clear screen in the outdoors wherein sunlight is bright. Also, micro LEDs are strong against a burn-in phenomenon and generate little heat, and thus a long lifespan without distortion is guaranteed. Micro LEDs may have a flip chip structure wherein an anode electrode and a cathode electrode are formed on the same first surface, and a light emitting surface is formed on a second surface positioned on the opposite side of the first surface wherein the electrodes are formed.

In the disclosure, one pixel may include at least three sub-pixels. One sub-pixel is a micro self-luminescence element for displaying images, and may mean, for example, a vertical cavity surface emitting laser (VCSEL) diode, a micro light emitting diode (LED), a blue micro light emitting diode (LED), or an ultraviolet micro light emitting diode (LED). Here, a blue micro LED may be a self-luminescence element that emits a light of a blue wavelength band (450-490 nm), and a UV micro LED may be a self-luminescence element that emits a light of an ultraviolet wavelength band (360-410 nm).

In the disclosure, one sub-pixel may include one micro self-luminescence element, and a color conversion layer and a color filter corresponding thereto. The color conversion layer may be excited by a light emitted from the micro self-luminescence element, and emit a color of a specific wavelength band. The color conversion layer may consist of a material including a nano phosphor or a quantum dot.

In the disclosure, one sub-pixel area means an area wherein the color of one sub-pixel is expressed by a light emitted from the one sub-pixel. In the disclosure, the area (the horizontal length x the vertical length) of one surface of a color conversion layer corresponding to a sub-pixel may be bigger than the area of a light emitting surface of the sub-pixel. In this case, the sub-pixel area may correspond to the area of the color conversion layer.

In the disclosure, on the substrate, a TFT layer on which a thin film transistor (TFT) circuit is formed may be arranged on the front surface, and on the rear surface, a power supply circuit supplying power to the TFT circuit and a data driving driver, a gate driving driver, and a timing controller controlling each driving driver may be arranged. A plurality of pixels arranged on the TFT layer may be driven by the TFT circuit.

In the disclosure, as the substrate, a glass substrate, a substrate based on a synthetic resin (e.g., Polyimide (PI), Polyethylene Terephthalate (PET), Polyethersulfone (PES), Polyethylene Naphthalate (PEN), Polycarbonate (PC), etc.), or a ceramic substrate may be used.

In the disclosure, on the front surface of the substrate, a TFT layer on which the TFT circuit is formed may be arranged, and a circuit may not be arranged on the rear surface of the substrate. The TFT layer may be formed integrally on the substrate or manufactured in the form of a separate film, and attached on one surface of the glass substrate.

In the disclosure, the front surface of the substrate may be divided into an active area and a dummy area. The active area may fall under an area occupied by the TFT layer on the front surface of the substrate, and the dummy area may fall under an area excluding the area occupied by the TFT layer on the front surface of the substrate.

In the disclosure, the edge area of the substrate may be the outermost area of the glass substrate. Also, the edge area of the substrate may be the remaining area excluding the area wherein a circuit of the substrate is formed. In addition, the edge area of the substrate may include a part of the front surface of the substrate adjacent to the side surface of the substrate, and a part of the rear surface of the substrate adjacent to the side surface of the substrate. The substrate may be formed in a quadrangle type. Specifically, the substrate may be formed as a rectangle or a square. The edge area of the substrate may include at least one side among the four sides of the glass substrate.

In the disclosure, the TFT constituting the TFT layer (or a backplane) is not limited to a specific structure or type. For example, the TFT cited in the disclosure may be implemented as an oxide TFT and an Si TFT (poly silicon, a-silicon), an organic TFT, a graphene TFT, etc. other than a low-temperature polycrystalline silicon (LTPS) TFT. Also, only a P-type (or an N-type) MOSFET may be made in an Si wafer CMOS process, and applied.

In the disclosure, the pixel driving method of the display module may be an active matrix (AM) driving method or a passive matrix (PM) driving method. The display module may form a pattern of wirings wherein each micro LED is electrically connected according to an AM driving method or a PM driving method.

In the disclosure, in one pixel area, a plurality of pulse amplitude modulation (PAM) control circuits may be arranged. In this case, each sub-pixel arranged in the one pixel area may be controlled by a corresponding PAM control circuit. Also, in one pixel area, a plurality of pulse width modulation (PWM) control circuits may be arranged. In this case, each sub-pixel arranged in the one pixel area may be controlled by a corresponding PWM control circuit.

In the disclosure, in one pixel area, a plurality of PAM control circuits and a plurality of PWM control circuits may be arranged together. In this case, some of the sub-pixels arranged in the one pixel area may be controlled by the PAM control circuits, and the others may be controlled through the PWM control circuits. Also, each sub-pixel may be controlled by a PAM control circuit and a PWM control circuit.

In the disclosure, the display module may include a plurality of side surface wirings having the thickness of a thin film which are arranged at regular intervals along a side surface of the TFT substrate.

In the disclosure, in the display module, a plurality of through wiring elements which are formed so as not be exposed on a side surface of the TFT substrate may be provided instead of a side surface wiring that is exposed on a side surface of the TFT substrate. Accordingly, the dummy area is minimized and the active area is maximized on the front surface of the TFT substrate, and thus the display module can become bezeless, and the mounting density of micro LEDs for the display module can be increased.

In the disclosure, the display module implementing a bezeless structure can provide a multi display device in a large size wherein the active area can be maximized in case a plurality of display modules are connected. In this case, as the dummy area is minimized, each display module may be formed such that pitches between each pixel of display modules adjacent to each other are maintained to be identical to pitches between each pixel in a single display module. Accordingly, it may be one method wherein seam is not made to be visible in connecting portions between each display module.

In the disclosure, a driving circuit may be implemented by a micro IC that is arranged in a pixel area and controls driving of at least 2n pixels. In the case of applying a micro IC to the display module, only a channel layer connecting the micro IC and each micro LED may be formed on the TFT layer (or the backplane) instead of a TFT.

In the disclosure, the display module may be installed and applied in a single unit on wearable devices, portable devices, handheld devices, and various kinds of electronic products or electronic components which need displays. Also, the display module may be applied as a matrix type to display devices such as monitors for personal computers (PCs), high resolution TVs and signage (or, digital signage), and electronic displays, etc. through a plurality of assembly arrangements.

Hereinafter, the display module according to an embodiment of the disclosure will be explained with reference to the drawings.

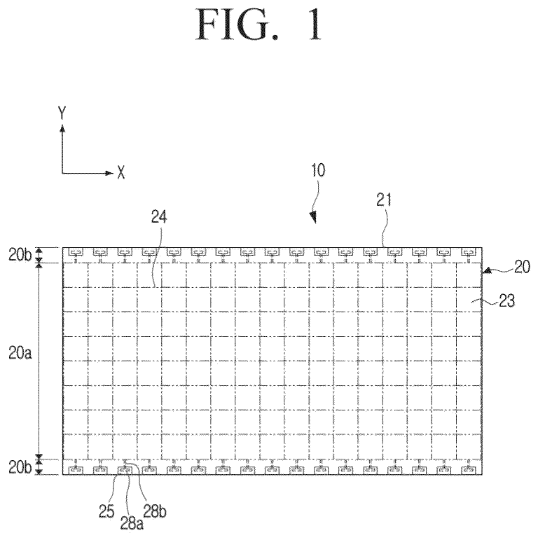

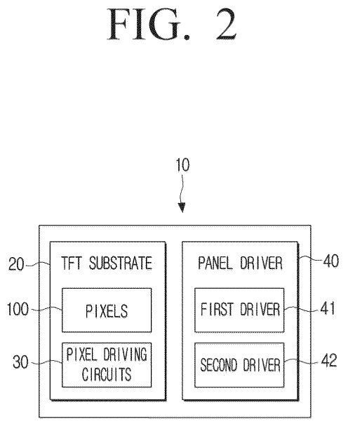

FIG. 1 is a schematic front view illustrating a display module according to the first embodiment of the disclosure, and FIG. 2 is a schematic block diagram illustrating the display module according to the first embodiment of the disclosure.

Referring to FIG. 1 and FIG. 2, the display module 10 according to the disclosure may include a TFT substrate 20 on which a plurality of pixel driving circuits 30 are formed, a plurality of pixels 100 arranged on the front surface of the TFT substrate 20, and a panel driver 40 that generates a control signal and provides the generated control signal to the plurality of pixel driving circuits 30.

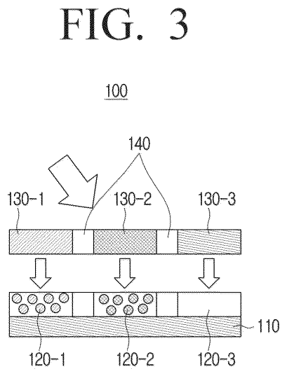

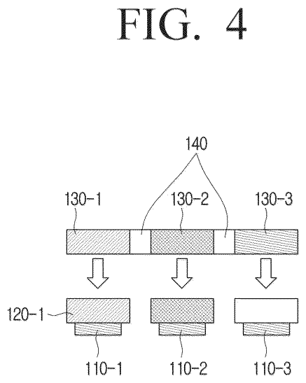

In the disclosure, one pixel may include a plurality of sub-pixels. Also, one sub-pixel may include one light source, and color conversion layers and color filters corresponding to each light source. Here, a light source is an inorganic self-light emitting diode, and it may be, for example, a vertical cavity surface emitting laser (VCSEL) diode or a micro light emitting diode (LED) having a size of 100 μm or smaller (e.g., 30 μm or smaller). A VCSEL diode or a micro LED may emit a light of a blue wavelength band (450-490 nm), or emit a light of an ultraviolet wavelength band (360-410 nm). The structure of the pixel 100 will be described in detail later with reference to FIG. 3 or FIG. 4.

The TFT substrate 20 may include a glass substrate 21, a TFT layer 23 including a thin film transistor (TFT) circuit on the front surface of the glass substrate 21, and a plurality of side surface wirings 25 that electrically connect the TFT circuit of the TFT layer 23 and the circuits arranged on the rear surface of the glass substrate 21.

In the disclosure, as an alternative of the glass substrate 21, a substrate based on a synthetic resin (e.g., Polyimide (PI), Polyethylene Terephthalate (PET), Polyethersulfone (PES), Polyethylene Naphthalate (PEN), Polycarbonate (PC), etc.) having a flexible material, or a ceramic substrate may be used.

The TFT substrate 20 may include an active area 20a that expresses images and a dummy area 20b that cannot express images on the front surface.

The active area 20a may be partitioned into a plurality of pixel areas 24 wherein a plurality of pixels are respectively arranged. The plurality of pixel areas 24 may be partitioned in various forms, and as an example, they may be partitioned in a matrix form. In one pixel area 24, one pixel 100 (refer to FIG. 3 or FIG. 4) may be included.

The dummy area 20b may be included in an edge area of the glass substrate 21, and a plurality of connection pads 28a may be arranged at regular intervals. Each of the plurality of connection pads 28a may be electrically connected with each pixel driving circuit 30 through the wiring 28b.

The number of the connection pads 28a formed in the dummy area 20b may vary according to the number of pixels implemented on the glass substrate, and may also vary according to the driving method of the TFT circuit arranged in the active area 20a. For example, compared to a case of the passive matrix (PM) driving method wherein the TFT circuit arranged in the active area 20a drives a plurality of pixels in a horizontal line and a vertical line, the active matrix (AM) driving method wherein each pixel is individually driven may need more wirings and connection pads. The TFT layer 23 may include a plurality of data signal lines arranged horizontally, a plurality of gate signal lines arranged vertically, and a plurality of pixel driving circuits 30 electrically connected to each line for controlling the plurality of pixels 100.

The panel driver 40 may be directly bonded to the TFT substrate 20 through a Chip on Glass (COG) or a Chip on Plastic (COP) bonding method. Alternatively, the panel driver 40 may be connected to the TFT substrate 20 through a separate FPCB by a Film on Glass (FOG) bonding method. The panel driver 40 may control light emission of the plurality of micro LEDs electrically connected to each of the plurality of pixel driving circuits 30 by driving the plurality of pixel driving circuits 30.

The panel driver 40 may control the plurality of pixel driving circuits 30 for each line through a first driver 41 and a second driver 42. The first driver 41 may generate a control signal for sequentially controlling a plurality of horizontal lines formed on the TFT substrate 20 by one line each per image frame, and transmit the generated control signal to the pixel driving circuits 30 respectively connected to the lines. The second driver 42 may generate a control signal for sequentially controlling a plurality of vertical lines formed on the TFT substrate 20 by one line each per image frame, and transmit the generated control signal to the pixel driving circuits 30 respectively connected to the lines.

FIG. 3 and FIG. 4 are diagrams illustrating the pixels 100 included in the display module according to an embodiment of the disclosure. As illustrated in FIG. 3, the pixels 100 may include a self-luminescence layer 110, first and second color conversion layers 120-1, 120-2, a transparent resin layer 120-3, first to third color filters 130-1, 130-2, 130-3, and partition walls 140.

The self-luminescence layer 110 may emit lights of the same color (e.g., a blue wavelength band 450-490 nm). In particular, as illustrated in FIG. 4, the self-luminescence layer 110 may include at least three self-luminescence elements 110-1, 110-2, 110-3. Here, the at least three self-luminescence elements 110-1, 110-2, 110-3 may be implemented as blue micro LEDs, but are not limited thereto.

Here, the first to third self-luminescence elements 110-1, 110-2, 110-3 may be electrically and physically connected to the TFT substrate 20 through an anisotropic conductive film (ACF) that was laminate-processed on the front surface of the TFT substrate 20. The first to third self-luminescence elements 110-1, 110-2, 110-3 may have a flip chip structure wherein two chip electrodes which are anode and cathode electrodes are formed on the opposite side of the light emitting surface.

The first to third self-luminescence elements 110-1, 110-2, 110-3 may consist of a square which has specific thickness and of which width and length are identical, or a rectangle of which width and length are different. In case the first to third self-luminescence elements 110-1, 110-2, 110-3 are implemented as micro LEDs, the first to third self-luminescence elements 110-1, 110-2, 110-3 can implement a real high dynamic range (HDR) and provide improved luminance and expressiveness of a black color, and a higher contrast ratio compared to OLEDs. The size of the micro LEDs may be smaller than or equal to 100 μm, or, e.g., smaller than or equal to 30 μm. In particular, the sizes of the first to third self-luminescence elements 110-1, 110-2, 110-3 may be identical.

As illustrated in FIG. 3, the first and second color conversion layers 120-1, 120-2 may be arranged on the self-luminescence layer 110, and may absorb a light emitted from the self-luminescence layer 110, and convert it into lights of different wavelength bands. Here, as illustrated in FIG. 4, the first color conversion layer 120-1 may be arranged on the light emitting surface of the first self-luminescence element 110-1, and the second color conversion layer 120-2 may be arranged on the light emitting surface of the second self-luminescence element 110-2.

The first color conversion layer 120-1 may include a color conversion material that emits lights of a red wavelength band, and the second color conversion layer 120-2 may include a color conversion material that emits lights of a green wavelength band.

Specifically, the first color conversion layer 120-1 may include a red nano phosphor that is excited by a light of a blue wavelength band emitted from the first self-luminescence element 110-1, and can emit a light of a red wavelength band. For example, the red nano phosphor may be SCASN(Si1-xCaxAlSiN3:Eu2+). In this case, the average value (d50) of the particle size distribution of the red nano phosphor may be smaller than 0.5 μm (e.g., 0.1 μm<d50<0.5 μm).

The second color conversion layer 120-2 may include a green nano phosphor that is excited by a light of a blue wavelength band emitted from the second self-luminescence element 110-2, and can emit a light of a green wavelength band. For example, the green nano phosphor may be β-SiAlON(Si6-zAlzOzN8-z:Eu2+) or SrGa2S4. In this case, the average value (d50) of the particle size distribution of the green nano phosphor may be smaller than 0.5 μm (e.g., 0.1 μm<d50<0.5 μm).

Alternatively, the first color conversion layer 120-1 may consist of a material including a red quantum dot that emits a light of a red wavelength band as an alternative of a red nano phosphor. In this case, the second color conversion layer 120-2 may consist of a material including a green quantum dot that emits a light of a green wavelength band as an alternative of a green nano phosphor.

The transparent resin layer 120-3 is arranged on the self-luminescence layer 110 (in particular, the light emitting surface of the third self-luminescence element 110-3), and is arranged side by side with the first and second color conversion layers 120-1, 120-2. Here, the transparent resin layer 120-3 may consist of a material that does not influence or that can minimize the transmissivity, the reflectance, and the refractive index of a light emitted from the third self-luminescence element 110-3. Meanwhile, the transparent resin layer 120-3 may be omitted depending on cases, and in this case, an air layer gets to exist on the light emitting surface side of the third self-luminescence element 110-3.

Also, the pixels 100 may include first and second color filters 130-1, 130-2 that respectively correspond to the first and second color conversion layers 120-1, 120-2, and may include a third color filter 130-3 corresponding to the transparent resin layer 120-3. Here, the first and second color filters 130-1, 130-2 may be arranged on the first and second color conversion layers 120-1, 120-2, and the third color filter 130-3 may be arranged side by side with the first and second color filters 130-1, 130-2.

The first color filter 130-1 may be a red color filter that makes a wavelength of the same color as the color of a light of a red wavelength band emitted from the first color conversion layer 120-1 pass through. The second color filter 130-2 may be a green color filter that makes a wavelength of the same color as the color of a light of a green wavelength band emitted from the second color conversion layer 120-2 pass through. The third color filter 130-3 may be a blue color filter that makes a wavelength of the same color as the color of a light of a blue wavelength band emitted from the self-luminescence layer 110 pass through. Here, the third color filter 130-3 may be implemented as an optical film that makes the direction of a light toward the front surface through refraction and reflection, and can thereby minimize wasted lights among lights emitted from the self-luminescence layer 110, and can improve luminance.

The pixels 110 may include partition walls 140 arranged between the first to third color filters 130-1, 130-2, 130-3. Here, the partition walls 140 may be in a matrix form that was formed in a lattice shape between the first to third color filters 130-1, 130-2, 130-3.

As described above, in the past, in a spectrum of a reflective light by an external light, the strength of red and green areas is shown to be relatively higher than that of the blue area. Thus, when the display module is turned off, a problem that the surface of the display module seems yellowish occurs. Also, due to such an uneven spectrum of a reflective light by an external light, a color mixing phenomenon may be generated when the display module is driven in a low grayscale.

Accordingly, a uniform spectrum of a reflective light by an external light can be implemented when the following formula 1 is satisfied.

$${A}_{r} \times {R}_{r} = {A}_{g} \times {R}_{g} = {A}_{b} \times {R}_{b} \qquad [ Formula 1 ]$$

Here, Aᵣ, A_{g}, A_{b} are respectively areas of the first to third color filters.

Also, Rᵣ, R_{g}, R_{b} are respectively reflectances of red, green, and blue colors in the upper parts of the first to third color filters 130-1, 130-2, 130-3.

In a related art structure, due to reflection by red and green color conversion layers, a first value which is a result of multiplying the size of the red color filter Aᵣ with a reflectance of a red color Rᵣ in the upper parts of the first to third color filters, and a second value which is a result of multiplying the size of the green color filter A_{g} with a reflectance of a green color R_{g} in the upper parts of the first to third color filters get to become bigger than a third value which is a result of multiplying the size of the blue color filter A_{b} with a reflectance of a blue color R_{b} in the upper parts of the first to third color filters, and thus there is a problem that the display module seems yellowish.

Accordingly, for resolving such a problem, in an embodiment of the disclosure, the third value which is a result of multiplying the size of the blue color filter Ab with a reflectance of a blue color R_{b} in the upper parts of the first to third color filters can be increased.

According to an embodiment of the disclosure, a first value which is a result of multiplying the size of the first color filter 130-1 with a reflectance of a red color in the upper parts of the first to third color filters 130-1, 130-2, 130-3, and a second value which is a result of multiplying the size of the second color filter 130-2 with a reflectance of a green color in the upper parts of the first to third color filters 130-1, 130-2, 130-3, and a third value which is a result of multiplying the size of the third color filter 130-3 with a reflectance of a blue color in the upper parts of the first to third color filters 130-1, 130-2, 130-3 may be within a threshold range. Here, the threshold range may be a range wherein the first to third values can mean almost identical values, and may mean a machining error range.

For increasing the area Ab of the blue color filter, according to an embodiment of the disclosure, the size of the third color filter 130-3 may be bigger than the sizes of the first and second color filters 130-1, 130-2.

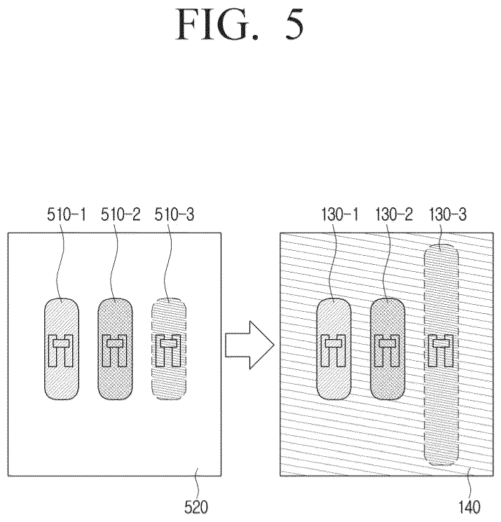

As an example, the sizes and the widths of the related art first to third color filters 510-1, 510-2, 510-3 are identical, as illustrated on the left side of FIG. 5. However, according to an embodiment of the disclosure, as illustrated on the right side of FIG. 5, the widths of the first to third color filters 130-1, 130-2, 130-3 are identical, but the length of the third color filter 130-3 may be longer than the lengths of the first and second color filters 130-1, 130-2.

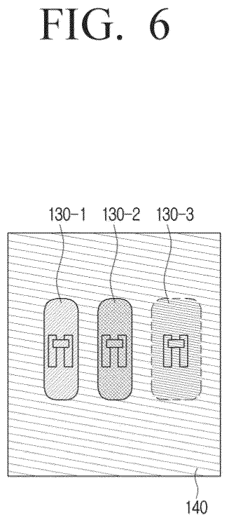

As an example, as illustrated in FIG. 6, the lengths of the first to third color filters 130-1, 130-2, 130-3 are identical, but the width of the third color filter 130-3 may be longer than the widths of the first and second color filters 130-1, 130-2.

As an example, the width and the length of the third color filter 130-3 may be longer than the widths and the lengths of the first and second color filters 130-1, 130-2.

As an example, one of the width or the length of the third color filter 130-3 may be smaller than one of the widths or the lengths of the first and second color filters 130-1, 130-2, but the size of the third color filter 130-3 may be bigger than the sizes of the first and second color filters 130-1, 130-2.

For increasing the reflectance R_{b} of a light in the blue area, according to an embodiment of the disclosure, blue dye may be added (or applied) to the partial walls 140 of the pixels 100. That is, as illustrated on the right side of FIG. 5, the related art partition walls 520 may be in a form of a black matrix, but for increasing the reflectance of a light in the blue area, blue dye of a specific ratio may be added (or applied) to the partial walls 140.

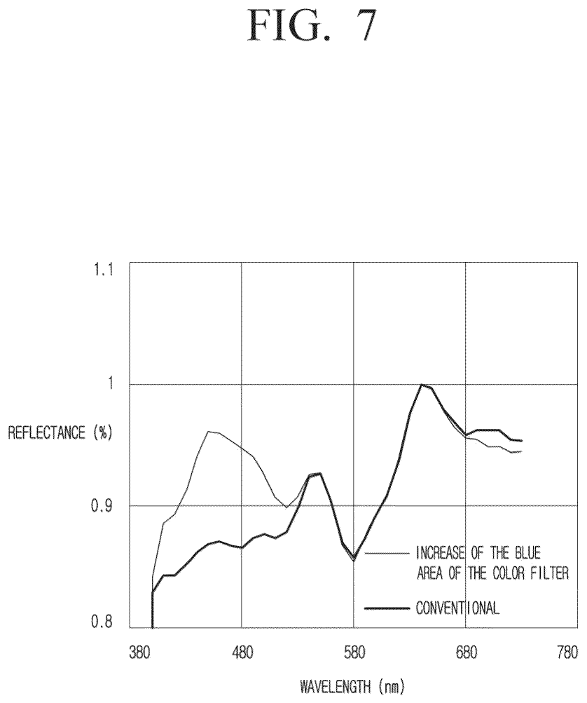

FIG. 7 is a diagram illustrating a spectrum for a reflective light of an external light obtained through a related art color filter and a spectrum for a reflective light of an external light obtained after extending the size of a blue color filter according to an embodiment of the disclosure.

That is, examining a spectrum for a reflective light of an external light obtained through a related art color filter, the reflectance of the blue light wavelength band 460 nm is smaller than the reflectance of the red light wavelength band 650 nm or the reflectance of the green light wavelength band 550 nm. However, examining a spectrum for a reflective light of an external light obtained after extending the size of a blue color filter according to an embodiment of the disclosure, the reflectance of the blue light wavelength band 460 nm increases, and thus the reflectance of the blue light wavelength band 460 nm, the reflectance of the red light wavelength band 650 nm, or the reflectance of the green light wavelength band 550 nm may be within the threshold range (e.g., 0.1). That is, by extending the size of the blue color filter, a spectrum for a reflective light that is more uniform than in the past can be obtained.

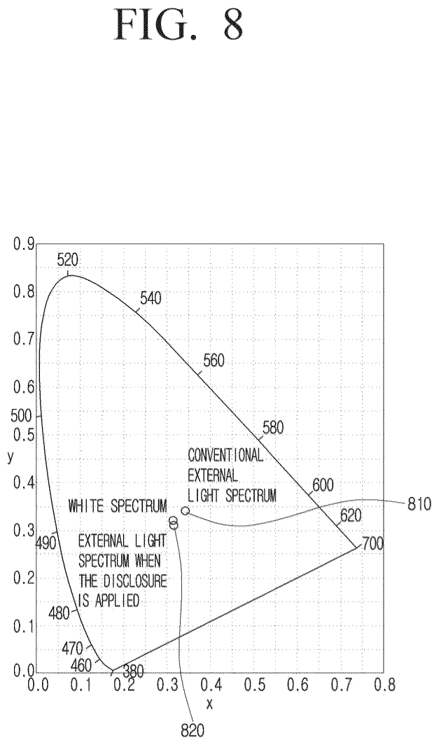

FIG. 8 is a diagram illustrating a CIE coordinate for a reflective light of an external light obtained through a related art color filter and a CIE coordinate for a reflective light of an external light obtained after extending the size of a blue color filter according to an embodiment of the disclosure.

Examining a CIE coordinate 810 for a reflective light of an external light obtained through a related art color filter and a CIE coordinate 820 for a reflective light of an external light obtained after extending the size of a blue color filter according to an embodiment of the disclosure, it can be identified that the CIE coordinate 820 for a reflective light according to an embodiment of the disclosure moved more to the white color than the related art CIE coordinate 810 for a reflective light.

As described above, by increasing the size of the third color filter (or the blue color filter) 130-3, and applying blue dye to the partition walls 140, a spectrum for a reflective light that is more uniform than in the past can be obtained. By this, when the display module 10 operates in a low grayscale, or is in a turned-off state, the problem that the display module 10 seems yellowish can be resolved.

In the above, each of the various embodiments of the disclosure was explained independently, but each embodiment does not necessarily have to be implemented solely, but the components and the operations of each embodiment may be implemented in combination with at least one other embodiment.

Also, while embodiments of the disclosure have been shown and described, the disclosure is not limited to the aforementioned specific embodiments, and it is apparent that various modifications may be made by those having ordinary skill in the technical field to which the disclosure belongs, without departing from the gist of the disclosure as claimed by the appended claims. Further, it is intended that such modifications are not to be interpreted independently from the technical idea or prospect of the disclosure.

What is claimed is:

1. A display module comprising:
a substrate; and
a plurality of pixels on the substrate,
wherein each pixel of the plurality of pixels comprises:
a self-luminescence layer;
a first color conversion layer and a second color conversion layer on the self-luminescence layer;
a first color filter and a second color filter on the first color conversion layer and the second color conversion layer, respectively;
a third color filter adjacent to the first color filter and the second color filter, and a size of the third color filter is larger than a size of the first color filter and a size of the second color filter; and
partition walls between the first color filter and the second color filter, and partition walls between the second color filter and the third color filter, and blue dye on the partition walls.

2. The display module of claim 1, wherein the self-luminescence layer comprises blue micro light emitting diodes (LEDs).

3. The display module of claim 1, wherein the first color conversion layer comprises a first color conversion material configured to emit lights of a red wavelength band, and
wherein the second color conversion layer comprises a second color conversion material configured to emit lights of a green wavelength band.

4. The display module of claim 3, wherein the first color conversion material included in the first color conversion layer is a red quantum dot or a red nano phosphor, and
wherein the second color conversion material included in the second color conversion layer is a green quantum dot or a green nano phosphor.

5. The display module of claim 1, comprising a transparent resin layer on self-luminescence elements and the transparent resin layer is adjacent to the first color conversion layer and the second color conversion layer.

6. The display module of claim 5, wherein the third color filter is on the transparent resin layer.

7. The display module of claim 5, wherein the self-luminescence layer comprises a first self-luminescence element, a second self-luminescence element, and a third self-luminescence element,
wherein the first color conversion layer on a light emitting surface of the first self-luminescence element,
wherein the second color conversion layer is on a light emitting surface of the second self-luminescence element, and
wherein the transparent resin layer is on a light emitting surface of the third self-luminescence element.

8. The display module of claim 7, wherein a size of the first self-luminescence element is identical to a size of the second self-luminescence element, which is identical to a size of the third self-luminescence element.

9. The display module of claim 1, wherein a first value corresponds to a result of multiplying the size of the first color filter with a reflectance of a red color in upper parts of the first color filter, the second color filter, and the third color filter,
wherein a second value corresponds to a result of multiplying the size of the second color filter with a reflectance of a green color in upper parts of the first color filter, the second color filter, and the third color filter,
wherein a third value corresponds to a result of multiplying the size of the third color filter with a reflectance of a blue color in upper parts of the first color filter, the second color filter, and the third color filter, and
wherein the first value, the second value, and the third value are within a threshold range.

10. The display module of claim 1, wherein widths of the first color filter, the second color filter, and the third color filter are identical, and a length of the third color filter is longer than a length of the first color filter and a length of second color filter.
